(19) United States
(12) Patent Application Publication
(10) Pub. No.: US 2014/0106577 A1
(43) Pub. Date: Apr. 17, 2014

(54) METHOD AND APPARATUS OF FORMING SILICON NITRIDE FILM

(71) Applicant: TOKYO ELECTRON LIMITED, Tokyo (JP)

(72) Inventors: Yamato TONEGAWA, Nirasaki City (JP); Keiji TABUKI, Niraski City (JP)

(73) Assignee: TOKYO ELECTRON LIMITED, Tokyo (JP)

(21) Appl. No.: 14/055,330

(22) Filed: Oct. 16, 2013

(30) Foreign Application Priority Data
Oct. 16, 2012 (JP) 2012-229186

(51) Int. Cl. H01L 21/02

(52) U.S. Cl. CPC H01L 21/02271; H01L 21/0217
USPC 438/791; 118/722

(57) ABSTRACT

Provided is a method of forming a silicon nitride film on an object to be processed, which includes: supplying a silicon raw material gas into a processing chamber; and supplying a nitridant gas into the processing chamber, wherein supplying the silicon raw material gas includes an initial supply stage in which the silicon raw material gas is initially supplied and a late supply stage following the initial supply stage, wherein a first internal pressure of the processing chamber defined in the initial supply stage is lower than a second internal pressure of the processing chamber defined in the late supply stage.

### CROSS-REFERENCE TO RELATED APPLICATION

This application claims the benefit of Japanese Patent Application No. 2012-229186, filed on Oct. 16, 2012, in the Japan Patent Office, the disclosure of which is incorporated herein in its entirety by reference.

### TECHNICAL FIELD

The present disclosure relates to a method and apparatus of forming a silicon nitride film.

### BACKGROUND

In a semiconductor integrated circuit device, a silicon nitride film has been used as a material for an etching stopper, a sidewall spacer, a stress liner or the like, as well as an insulator. For example, there is a method which forms a silicon nitride film using an ALD (Atomic Layer Deposition) technique. A film forming apparatus for use in the silicon nitride film forming method includes two gas supply channels for a silicon raw material gas: one is provided with a gas reservoir and the other is provided without the gas reservoir. In such a film forming apparatus, for example, a silicon raw material gas is supplied through the gas supply channel without the gas reservoir so as to form a thin film having a thickness of 60 angstrom or less, while the silicon raw material gas is supplied through the gas supply channel with the gas reservoir so as to form a thick film having a thickness of more than 60 angstrom. In this way, the silicon nitride film may be formed to have good uniformity of film thickness, either thin or thick.

A stoichiometric composition ratio of the silicon nitride film is “Si:N=3:4 (Si₃N₄).” However, the silicon nitride film may have various composition ratios depending on a film forming method. The composition of the silicon nitride film is related to a refractive index of the film. As such, the composition of the silicon nitride film can be obtained by inspecting the refractive index of the silicon nitride film. For example, the refractive index of the Si₃N₄ film is about 2.0 (at a wavelength of about 633 nm). If the refractive index is larger than about 2.0, such as 2.1, 2.2 or the like, the silicon nitride film becomes a silicon (Si)-rich film in the Si₃N₄ composition. On the contrary, if the refractive index is less than about 2.0, such as 1.9, 1.8 or the like, the silicon nitride film becomes a nitrogen (N)-rich film in the Si₃N₄ composition.

The composition of the silicon nitride film influences, for example, a film stress. For example, for the Si-rich composition, the film stress is small, while for the N-rich composition, the film stress increases.

Since the composition of the silicon nitride film influences the film stress, for example, formation of a silicon nitride film having a small film stress requires formation of the Si-rich film (in the Si₃N₄ composition) having the refractive index of 2.1, 2.2 or the like. The formation of the Si-rich film (in the Si₃N₄ composition) is achieved by, e.g., prolonging a supply time of the silicon raw material gas compared to the case where a silicon nitride film having a refractive index of about 2.0 is formed.

However, such a prolongation causes the formed silicon nitride film to have a strong tendency to be thick and convex at a periphery of a wafer and thin and concave at the central portion thereof. This results in a degraded uniformity of film thickness.

### SUMMARY

The present disclosure provides some embodiments of a film forming method and apparatus, which are capable of forming a silicon nitride film without degrading an in-plane uniformity of film thickness even for a Si-rich silicon nitride film (in Si₃N₄ composition).

According to one embodiment of the present disclosure, provided is a method of forming a silicon nitride film on an object to be processed, the method including: supplying a silicon raw material gas into a processing chamber; and supplying a nitridant gas into the processing chamber, wherein supplying the silicon raw material gas includes an initial supply stage in which the silicon raw material gas is initially supplied and a late supply stage following the initial supply stage, wherein a first internal pressure of the processing chamber defined in the initial supply stage is lower than a second internal pressure of the processing chamber defined in the late supply stage.

According to another embodiment of the present disclosure, provided is a film forming apparatus, including: a processing chamber in which a film forming processing is performed on an object to be processed; a silicon raw material gas supply mechanism configured to supply a silicon raw material gas into the processing chamber; a nitridant gas supply mechanism configured to supply a nitridant gas into the processing chamber; a pressure adjusting mechanism configured to adjust an internal pressure of the processing chamber; a tank configured to be temporarily charged with the silicon raw material gas supplied from the silicon raw material gas supply mechanism; and a control unit configured to control the film forming processing such that the aforementioned method is performed.

According to another embodiment of the present disclosure, provided is a film forming apparatus, including: a processing chamber in which a film forming processing is performed on an object to be processed; a silicon raw material gas supply mechanism configured to supply a silicon raw material gas into the processing chamber; a nitridant gas supply mechanism configured to supply a nitridant gas into the processing chamber; a pressure adjusting mechanism configured to adjust an internal pressure of the processing chamber; and a control unit configured to control the film forming processing such that the aforementioned method is performed.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view schematically showing an example of a film forming apparatus which is capable of performing a silicon nitride film forming method according to a first embodiment of the present disclosure.

FIG. 2 is a cross sectional view showing a relationship between a supply time of a silicon raw material gas and a shape of a formed silicon nitride film.

FIG. 3 is a timing chart showing an example of a silicon nitride film forming method according to the first embodiment of the present disclosure.

FIGS. 4A to 4C are views showing operation states of a gas supply adjusting unit provided in the film forming apparatus shown in FIG. 1;

FIG. 5 is a view showing a change in internal pressure of a processing chamber in a supply process of a silicon raw material gas.

FIG. 6A is a cross sectional view showing a shape of a silicon nitride film formed in the absence of an initial supply stage I, as a reference example.

FIG. 6B is a cross sectional view showing a relationship between a charge time and shapes of the silicon nitride film in the presence of the initial supply stage I.

FIG. 7 is a view showing a relationship between a supply time of a silicon raw material gas in a late supply stage II, a refractive index of a silicon nitride film and a cycle rate when the silicon nitride film is formed.

FIG. 8 is a view showing a relationship between a position of a boat slot and a refractive index of a silicon nitride film.

FIGS. 9A to 9C are views showing main operation states of another gas supply adjusting unit according to a second embodiment of the present disclosure, which is provided in the film forming apparatus shown in FIG. 1.

FIG. 10 is a sectional view schematically showing a film forming apparatus according to a third embodiment, which is capable of performing the silicon nitride film forming method according to the first embodiment of the present disclosure.

FIG. 11 is a view showing a relationship between an opening degree of an automatic pressure controller (APC) and an internal pressure of a processing chamber in a supply process of a silicon raw material gas according to the third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings. In the drawings, like reference numerals indicate like elements.

### (Film Forming Apparatus)

First, an example of a film forming apparatus, which is capable of performing a silicon nitride film forming method according to an embodiment of the present disclosure, will be described.

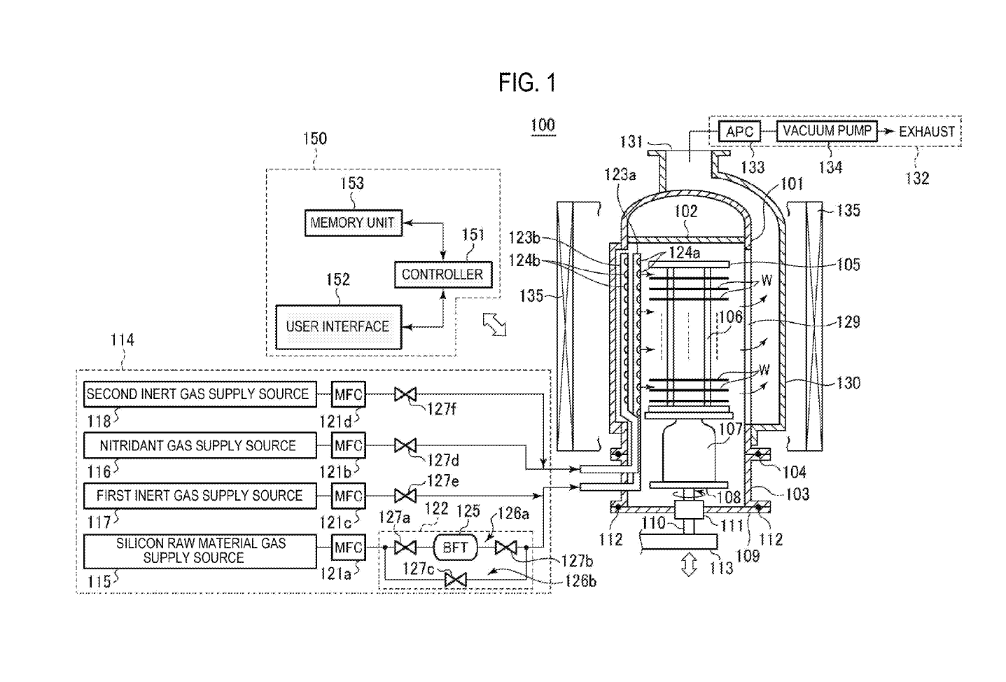

FIG. 1 is a sectional view schematically showing an example of a film forming apparatus capable of performing a silicon nitride film forming method according to a first embodiment of the present disclosure.

As shown in FIG. 1, a film forming apparatus 100 includes a cylindrical processing chamber 101 having a ceiling with a bottom end opened. The entirety of the processing chamber 101 is formed of, e.g., quartz. A quartz ceiling plate 102 is located at the ceiling inside the processing chamber 101. Also, for example, a manifold 103, which is formed of a stainless steel to have a cylindrical shape, is connected to a lower end opening portion of the processing chamber 101 through a sealing member 104 such as an O-ring.

The manifold 103 supports a lower end portion of the processing chamber 101. A wafer boat 105 of quartz, in which a plurality of (e.g., 50 to 120) semiconductor wafers (e.g., silicon wafers) W are loaded as objects to be processed in multiple stages, is insertable into the processing chamber 101 through a lower portion of the manifold 103. The wafer boat 105 includes a plurality of supporting pillars 106, and the plurality of wafers W are supported by grooves (not shown) which are formed in each of the supporting pillars 106.

The wafer boat 105 is loaded on a table 108 with a heat insulating tube 107 of quartz therebetween. The table 108 is supported on a rotation shaft 110 that passes through a cover part 109. The cover part 109 is made of, e.g., a stainless steel, and opens or closes a lower end opening portion of the manifold 103. A magnetic fluid seal 111 is disposed at a through portion of the rotation shaft 110. The magnetic fluid seal 111 closely seals and rotatably supports the rotation shaft 110. Also, for example, a seal member 112 such as an O-ring is disposed between a periphery of the cover part 109 and a lower end portion of the manifold 103, thus maintaining sealability in the processing chamber 101. The rotation shaft 110, for example, is disposed at a front end of an arm 113 that is supported by an ascending/descending instrument such as a boat elevator. Accordingly, the wafer boat 105 and the cover part 109 are elevated in an integrated manner to be inserted into/separated from the processing chamber 101.

The film forming apparatus 100 includes a process gas supply mechanism 114 configured to supply a process gas into the processing chamber 101.

The process gas supply mechanism 114 includes a silicon raw material gas supply source 115, a nitridant gas supply source 116, a first inert gas supply source 117, and a second inert gas supply source 118. Examples of the silicon raw material gas may include a dichlorosilane (DCS: SiH₂Cl₂) gas, examples of the nitridant gas may include an ammonia (NH₃) gas, and examples of the inert gas may include a nitrogen (N₂) gas.

The silicon raw material gas supply source 115 is connected to a first dispersing nozzle 123a through a mass flow controller (MFC) 121a and a gas supply adjusting unit 122. The first dispersing nozzle 123a is made of a quartz pipe, which pierces a sidewall of the manifold 103 inward, bends upward and extends vertically. At a vertical portion of the first dispersing nozzle 123a, a plurality of gas discharge holes 124a are formed spaced apart from each other at a predetermined interval. The silicon raw material gas is discharged in an approximately uniform manner from the respective gas discharge holes 124a into the processing chamber 101 in the horizontal direction.

The gas supply adjusting unit 122 has two gas supply channels provided therein: one is a gas supply channel 126a with a buffer tank (BFT) 125 which is capable of being temporarily charged with gas; and the other is a gas supply channel 126b without a buffer tank. An opening/closing valve 127a is disposed at a front side of a gas inlet of the buffer tank 125 in the gas supply channel 126a, and an opening/closing valve 127b is disposed at a back side of a gas outlet thereof. The opening/closing valves 127a and 127b respectively control a charge of the silicon raw material gas into the buffer tank 125 and a discharge of the silicon raw material gas therefrom. The gas supply channel 126b includes an opening/closing valve 127c. The opening/closing valve 127c controls opening and closing of the gas supply channel 126b.

The nitridant gas supply source 116 is connected to a second dispersing nozzle 123b through a mass flow controller (MFC) 121b and an opening/closing valve 127d. The second dispersing nozzle 123b is also made of a quartz pipe like the first dispersing nozzle 123a, which pierces the sidewall of the manifold 103 inward, bends upward and extends vertically. At a vertical portion of the second dispersing nozzle 123b, a plurality of gas discharge holes 124b are formed where each of the holes 124b are spaced apart from each other at a predetermined interval. A nitridant gas is discharged in an approximately uniform manner from the respective gas discharge holes 124b into the processing chamber 101 in the horizontal direction.

The first inert gas supply source 117 is connected to the first dispersing nozzle 123a through a mass flow controller (MFC) 121c and an opening/closing valve 127e. The inert gas is used as a purge gas for purging, for example, the interior of the processing chamber 101. Also, since the first inert gas supply source 117 is connected to the first dispersing nozzle 123a configured to discharge the silicon raw material gas therefrom, the inert gas may also be used as a dilution gas for diluting the silicon raw material gas, if necessary.

The second inert gas supply source 118 is connected to the second dispersing nozzle 123b through a mass flow controller (MFC) 121d and an opening/closing valve 127f. The inert gas is used as a purge gas for purging, for example, the interior of the processing chamber 101. The inert gas may also be used as a dilution gas for diluting the nitridant gas, if necessary.

An exhaust vent 129 configured to exhaust gas from the processing chamber 101 is formed in a portion opposite to the first and second dispersing nozzles 123a and 123b, respectively, in the processing chamber 101. The exhaust vent 129 has an elongated shape formed by chipping the sidewall of the processing chamber 101 in the vertical direction. At a portion corresponding to the exhaust vent 129 of the processing chamber 101, an exhaust vent cover member 130 with a C-shaped section is installed by welding to cover the exhaust vent 129. The exhaust vent cover member 130 extends upward along the sidewall of the processing chamber 101, and defines a gas outlet 131 at the top of the processing chamber 101.

An exhaust mechanism 132 is connected to the gas outlet 131. The exhaust mechanism 132 includes a pressure controller (e.g., an automatic pressure controller (APC) 133) connected to the gas outlet 131 and an exhaustion device (e.g., a vacuum pump 134) connected to the automatic pressure controller 133. The exhaust mechanism 132 exhausts the processing chamber 101 so as to discharge the process gas used for the process so that an internal pressure of the processing chamber 101 is adjusted to a predetermined process pressure.

A cylindrical heating unit 135 is installed on the outer periphery of the processing chamber 101. The heating unit 135 activates a gas supplied into the processing chamber 101, and heats objects to be processed (e.g., the silicon wafers W in this embodiment) loaded in the processing chamber 101.

A control unit 150 is connected to the film forming apparatus 100. The control unit 150 is provided with, for example, a process controller 151 including a microprocessor (e.g., a computer). The control of each component of the film forming apparatus 100 is performed by the process controller 151. A user interface 152 and a memory unit 153 are connected to the process controller 151.

The user interface 152 is provided with an input unit including a touch panel display or a keyboard that enables an operator to input a command for managing the film forming apparatus 100 and a display unit that visualizes and displays an operating state of the film forming apparatus 100.

The memory unit 153 stores a control program for executing various processes in the film forming apparatus 100 under the control of the process controller 151 and a program (i.e., a process recipe) for executing a process in each component of the film forming apparatus 100 according to process conditions. For example, the process recipe is stored in a memory medium of the memory unit 153. The memory medium may include a hard disk, a semiconductor memory, a CD-ROM, a DVD, and a portable memory such as a flash memory. The process recipe may be transmitted from other device through a dedicated line.

If necessary, the process recipe is read from the memory unit 153 in response to a command received from the user interface 152, and the process controller 151 executes a process according to the read recipe. Accordingly, the film forming apparatus 100 performs a desired process under the control of the process controller 151.

The silicon nitride film forming method according to the embodiment of the present disclosure is performed using the film forming apparatus 100 as shown in FIG. 1, which includes the process controller 151 configured to control the film forming apparatus 100, which will be described later.

Hereinafter, an example of the silicon nitride film forming method according to the first embodiment of the present disclosure will be described.

### First Embodiment

For example, in order to form a silicon nitride film having a Si-rich composition and a small film stress, a supply time of a silicon raw material gas such as a DCS gas needs to be longer than a case where a silicon nitride film having a refractive index of about 2.0 is formed. However, if the supply time of the DCS gas is increased, the silicon nitride film formed on an object to be processed (e.g., the wafer) has an increased thickness in the periphery of the wafer, thereby having a strong tendency to form a concave shape.

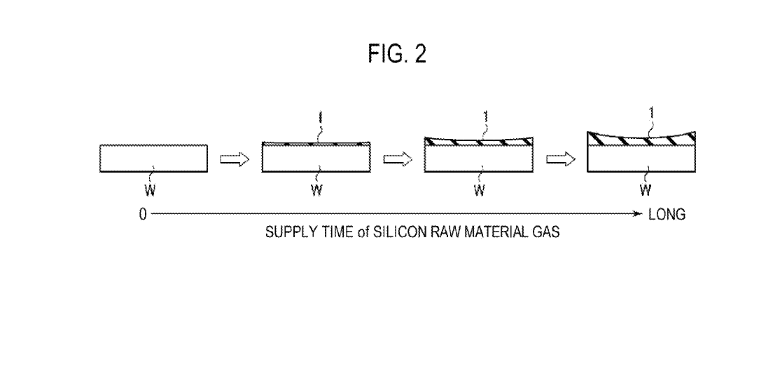

FIG. 2 is a cross sectional view showing a relationship between a supply time of a silicon raw material gas supply time and a shape of a formed silicon nitride film.

As shown in FIG. 2, if a proportion of silicon contained in a silicon nitride film 1 is increased by increasing the supply time of the DCS gas, the silicon nitride film 1 formed on the wafer W has a strong tendency to have a concave shape, which causes degradation in wafer in-plane uniformity of a thickness of the silicon nitride film 1.

To address the above problem, the silicon nitride film forming method according to the first embodiment includes two divided supply stages for the silicon raw material gas: an initial supply stage and a late supply stage following the initial supply stage. Further, in the initial supply stage, the internal pressure of the processing chamber 101 where a film is formed is defined as a first pressure. Whereas, in the late supply stage, the internal pressure of the processing chamber 101 is defined as a second pressure lower than the first pressure.

In the supply process of the silicon raw material gas, the provision of the initial supply stage and the late supply stage can improve the wafer in-plane uniformity of thickness of the silicon nitride film formed on the semiconductor wafer even for a Si-rich silicon nitride film (in the Si₃N₄ composition), which will be described later. In the first embodiment, a relationship between the first pressure and the second pressure is realized using the gas supply adjusting unit 122 of the film forming apparatus 100 shown in FIG. 1.

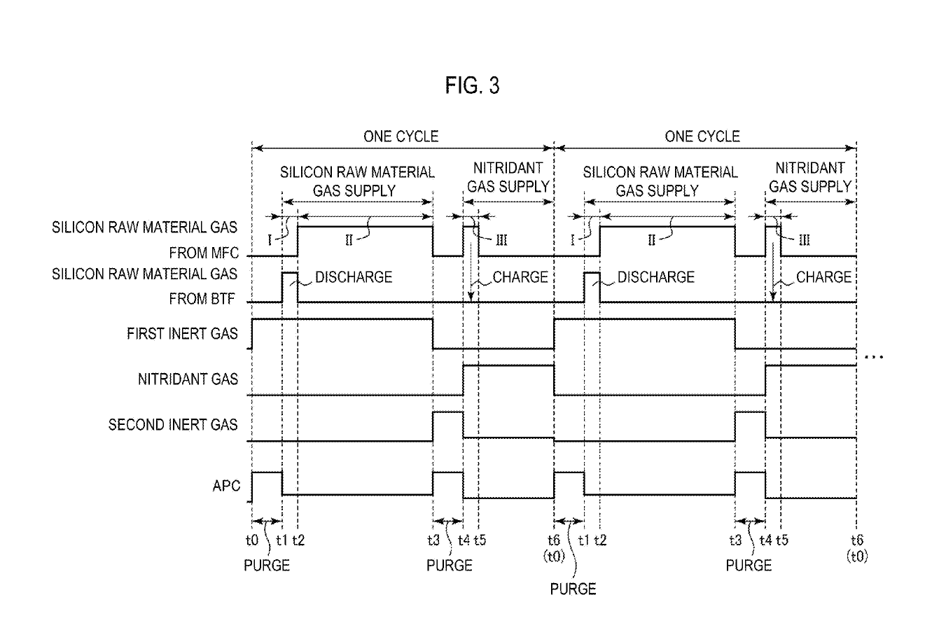

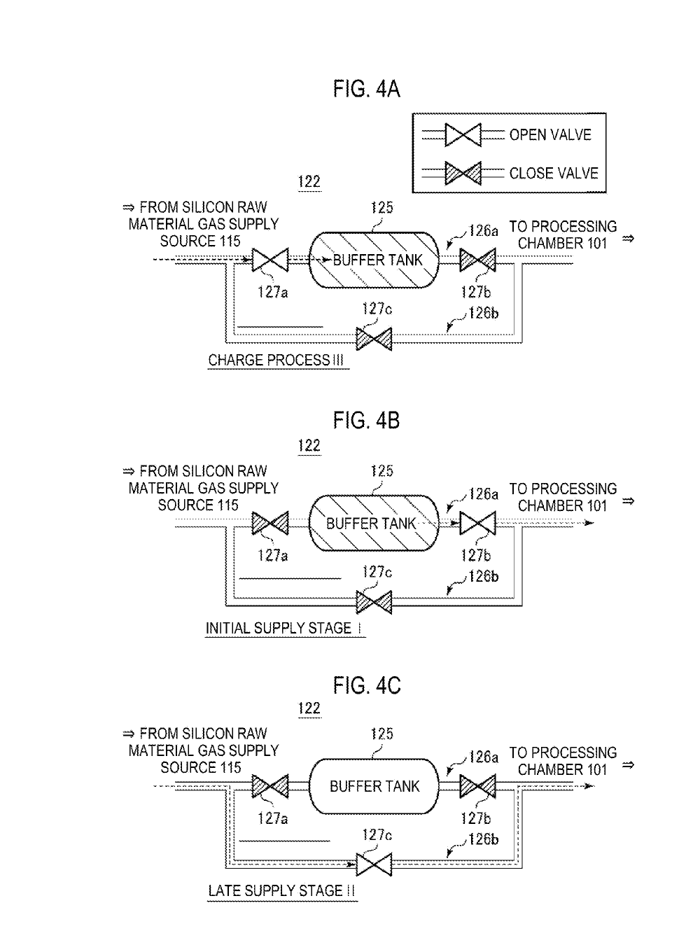

FIG. 3 is a timing chart showing an example of the silicon nitride film forming method according to the first embodiment of the present disclosure. FIGS. 4A to 4C are views showing operation states of the gas supply adjusting unit 122.

As shown in FIG. 3, the silicon nitride film forming method according to the first embodiment is a thermal ALD method in which the silicon raw material gas and the nitridant gas are alternately supplied. Hereinafter, main processes will be described in sequence.

<0. Charge Process of Buffer Tank 125 with Silicon Raw Material Gas>

First, prior to the film forming processing, the buffer tank (BFT) 125 of the film forming apparatus 100 shown in FIG. 1 is charged with the silicon raw material gas. An example of the silicon raw material gas is the DCS gas.

As shown in FIG. 4A, the charge of the buffer tank 125 with the silicon raw material gas is implemented by closing the opening/closing valve 127b disposed at the gas outlet side in the gas supply channel 126a and the opening/closing valve 127c in the gas supply channel 126b and opening the opening/closing valve 127a disposed at the gas inlet side in the gas supply channel 126a. In such a state, the silicon raw material gas is supplied into the buffer tank 125 from the silicon raw material gas supply source 115 through the mass flow controller 121a. It is practical that an internal pressure of the charged buffer tank 125 falls within a range, for example, of 13,300 to 53,200 Pa (100 to 400 Torr) (herein, 1 Torr is about 133 Pa).

### <1. Purge Process>

Upon completing the charge of the buffer tank 125, the processing chamber 101 is subjected to a purge process. Specifically, an opening degree of the APC 133 is set to be “OPEN (opening degree=100%)” and a first inert gas (for example, a nitrogen gas) is supplied from the first inert gas supply source 117 into the processing chamber 101 such that the interior of the processing chamber 101 is purged with the first inert gas (during a time interval between t0 to t1 in FIG. 3).

### <2. Supply Process of Silicon Raw Material Gas>

Upon completing the purge process, the supply of the silicon raw material gas (for example, the DCS gas) is initiated. A silicon film is formed on the wafer W accommodated in the processing chamber 101 by supplying the silicon raw material gas into the processing chamber 101. During the supply process of the silicon raw material gas, the wafer W in the wafer boat 105 is rotated.

As described above, in this embodiment, the supply process of the silicon raw material gas has the two supply stages, i.e., the initial supply stage I of the silicon raw material gas and the late supply stage II following the initial supply stage I.

Initial Supply Stage I

In the initial supply stage I, the opening degree of the APC 133 is reduced to, e.g., 25%, and in such a state, the silicon raw material gas is discharged from the buffer tank 125. As a result, the silicon raw material gas is supplied into the processing chamber 101 (during a time interval between t1 to t2 in FIG. 3). The discharge of the silicon raw material gas from the buffer tank 125 is performed by closing the opening/closing valve 127a disposed at the gas inlet side in the gas supply channel 126a and the opening/closing valve 127c in the gas supply channel 126b and opening the opening/closing valve 127b disposed at the gas outlet side in the gas supply channel 126a, as shown in FIG. 4B.

An example of processing conditions in the initial supply stage I is as follows:

Processing Temperature: 300 to 650 degrees C.

Processing Pressure: more than 133 Pa and not more than 665 Pa (more than 1 Torr and not more than 5 Torr)

Flow Rate of N₂ Gas: 4000 sccm

Flow Rate of DCS Gas: Discharge from BFT

Processing Time: 3 sec

Opening Degree of APC: 25%

Late Supply Stage II

The late supply stage II is followed by the initial supply stage I. In the late supply stage II, in a state where the opening degree of the APC 133 is maintained at, e.g., 25%, the silicon raw material gas is supplied from the silicon raw material gas supply source 115 into the processing chamber 101 with its flow rate being adjusted by the MFC 121a (during a time interval between t2 to t3 in FIG. 3). The supply of the silicon raw material gas through the MFC 121a is performed by closing the opening/closing valve 127a disposed at the gas inlet side in the gas supply channel 126a and the opening/closing valve 127b disposed at the gas outlet side thereof, and opening the opening/closing valve 127c in the gas supply channel 126b, as shown in FIG. 4C.

An example of processing conditions in the late supply stage II is as follows:

Processing Temperature: 300 to 650 degrees C.

Processing Pressure: 133 Pa (1 Torr)

Flow Rate of N₂ Gas: 4000 sccm

Flow Rate of DCS Gas: 2000 sccm

Processing Time: 45 sec

Opening Degree of APC: 25%

### <3. Purge Process>

Upon completing the supply process of the silicon raw material gas, the processing chamber 101 is subjected to a subsequent purge process. The opening degree of the APC 133 is set to be “OPEN” and a second inert gas (for example, the nitrogen gas) is supplied from the second inert gas supply source 118 into the processing chamber 101 such that the interior of the processing chamber 101 is purged with the second inert gas (during a time interval between t3 to t4 in FIG. 3).

<4. Supply Process of Nitridant Gas and Charge of Buffer Tank 125 with Nitridant Gas>

Upon completing the subsequent purge process, the supply process of the nitridant gas (for example, an ammonia gas) is initiated. The silicon film formed on the wafer W is nitrided by supplying the nitridant gas into the processing chamber 101. The supply process of the nitridant gas is performed by reducing the opening degree of the APC 133 to, e.g., 5%, and supplying the nitridant gas into the processing chamber 101 from the nitridant gas supply source 116 while adjusting its flow rate by the MFC 121b (during a time interval between t4 to t6 in FIG. 3). Also, during the supply process of the nitridant gas, the wafer W in the wafer boat 105 is rotated.

An example of processing conditions in the supply process of the nitridant gas is as follows:

Processing Temperature: 300 to 650 degrees C.

Processing Pressure: 213 Pa (1.6 Torr)

Flow Rate of N₂ Gas: 200 sccm

Flow Rate of NH₃ Gas: 5000 sccm

Processing Time: 30 sec

Opening Degree of APC: 5%

With this, one cycle of forming the silicon film and nitriding the same is terminated. Thereafter, the silicon nitride film 1 is formed on the wafer W by repeating the one cycle shown in FIG. 3 until the silicon nitride film 1 has a designed thickness.

Further, in this embodiment, the charge of the discharged buffer tank 125 with the silicon raw material gas is performed in the course of the supply process of the nitridant gas (during a time interval between t4 to t5, indicated by a referential mark III in FIG. 3). This charge process is performed in the same way as the above-described charge process of the buffer tank 125.

In this way, the charge process III of charging the buffer tank 125 with the silicon raw material gas is performed in parallel with the supply process of the nitridant gas so that the charge of the buffer tank 125 with the silicon raw material gas is terminated in the course of the supply process of the nitridant gas. On this account, according to this embodiment, in spite of the presence of the additional charge process III, it is possible to prevent the increase in time for the extra cycle. The time for the charge process III is 4 sec in this embodiment.

### <Internal Pressure of Processing Chamber 101 in Supply Process of Silicon Raw Material Gas>

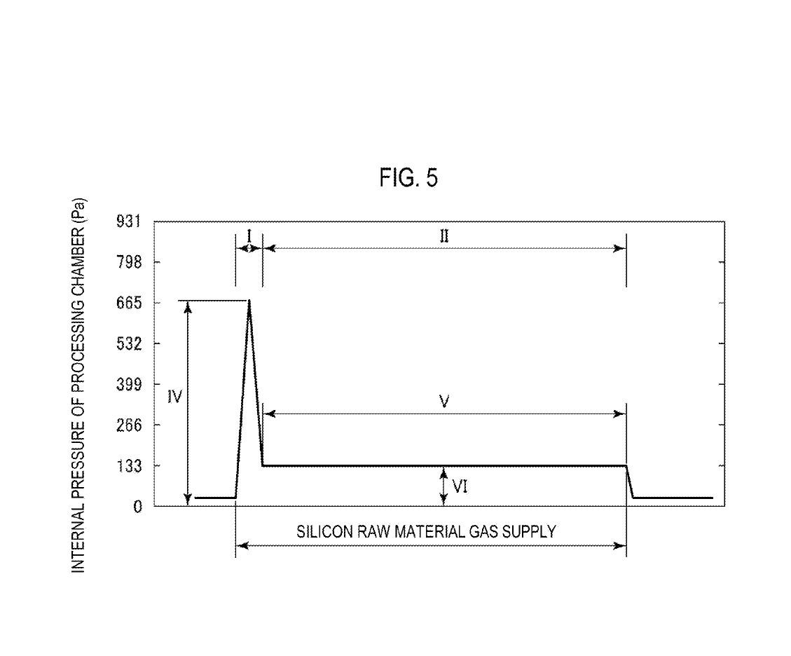

FIG. 5 is a view showing a change in the internal pressure of the processing chamber 101 in the supply process of the silicon raw material gas.

As shown in FIG. 5, in the initial supply stage I, the silicon raw material gas discharged from the buffer tank 125 is supplied into the processing chamber 101. On this account, the internal pressure of the processing chamber 101 temporarily and rapidly increases up to, e.g., about 665 Pa or so (see a referential mark IV). After the silicon raw material gas charged in the buffer tank 125 is completely discharged, the internal pressure of the processing chamber 101 rapidly decreases.

In the subsequent late supply stage II, without using the buffer tank 125, the silicon raw material gas is supplied from the silicon raw material gas supply source 115 into the processing chamber 101 with its flow rate being adjusted by the MFC 121a. On this account, it is possible to stabilize the internal pressure of the processing chamber 101 at a pressure lower than the pressure temporarily increased in the initial supply stage I, for example, at about 133 Pa or so (see a referential mark VI).

A peak value (indicated by the referential mark IV) of the temporarily increased pressure in the initial supply stage I can be controlled by, e.g., adjusting the charge time of the charge process III shown in FIG. 3.

The internal pressure of the buffer tank 125 can further be increased, for example, by maintaining the flow rate of the silicon raw material gas at a constant level by the MFC 121a and prolonging the charge time of the charge process III. This makes it possible to discharge the silicon raw material gas from the buffer tank 125 at a higher rate. Therefore, it is possible to set the peak value IV of the temporarily increased pressure to be higher.

On the contrary, the internal pressure of the buffer tank 125 can be reduced by setting the flow rate of the silicon raw material gas to be equal to the above-described flow rate and reducing only the charge time of the charge process III. This reduces an amount of the silicon raw material gas to be discharged from the buffer tank 125, which makes it possible to set the peak value IV of the temporarily increased pressure to a lower value.

### <Relationship Between Charge Time and Shape of Silicon Nitride Film>

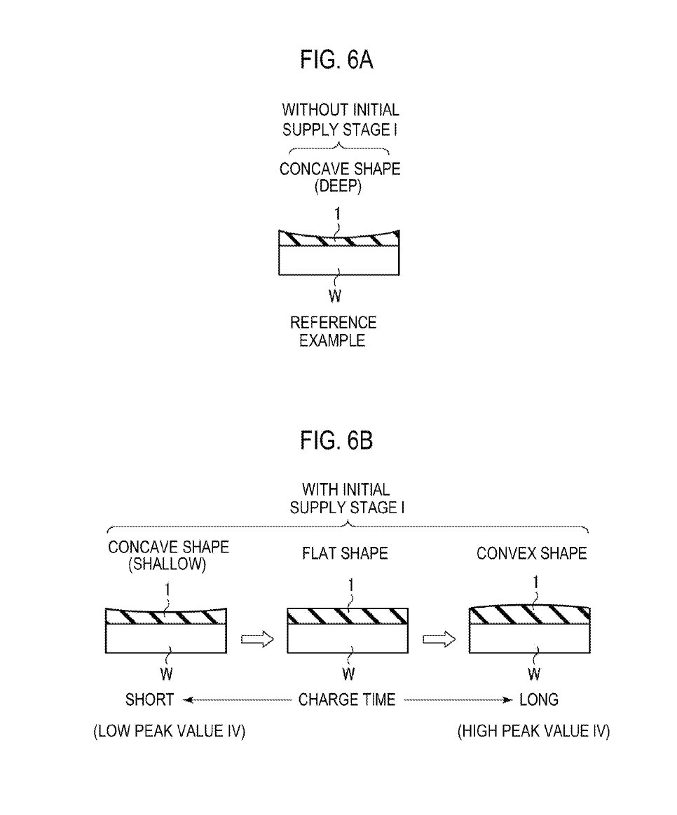

FIG. 6A is a cross sectional view showing a shape of a formed silicon nitride film in the absence of the initial supply stage I, as a reference example; and FIG. 6B is a cross sectional view showing a relationship between the charge time and shapes of the silicon nitride film.

As shown in FIG. 6A, when the silicon nitride film 1 as the Si-rich film having a refractive index of, e.g., about 2.1 to 2.2, is formed in the absence of the initial supply stage I, the silicon nitride film 1 becomes thick at the periphery of the wafer W, thereby forming a deeply concave shape.

However, as shown in FIG. 6B, if the initial supply stage I is provided, the concave portion of the silicon nitride film 1 becomes gradually shallow. The silicon nitride film 1 tends to have a convex shape on the contrary as the peak value IV is increased by prolonging the charge time of the silicon raw material gas into the buffer tank 125. It is likely that the silicon raw material gas may be spread sufficiently wide to the center of the wafer W when the internal pressure of the processing chamber 101 in the initial supply stage I is larger than the internal pressure of the processing chamber 101 in the late supply stage II,

In addition, during transition of the silicon nitride film 1 from the concave shape to the convex shape, the charge time, i.e., the peak value IV, which makes the shape of the silicon nitride film 1 flat, surely exists. This charge time is an optimal value capable of improving the wafer in-plane uniformity.

Therefore, according to the silicon nitride film forming method of the first embodiment of the present disclosure, the charge time in the charge process III is set to the optimal value capable of improving the wafer in-plane uniformity. Thus, it possible to form the silicon nitride film without degrading the wafer in-plane uniformity of thickness thereof even for the Si-rich silicon nitride film 1 (in the Si₃N₄ composition).

### <Relationship Between Processing Time of Late Supply Stage II and Refractive Index (Composition Ratio) of Silicon Nitride Film>

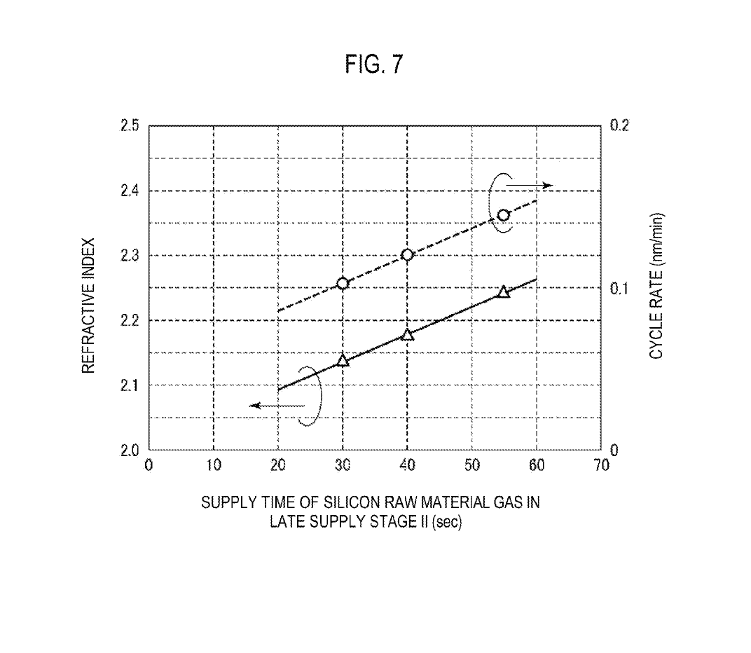

FIG. 7 is a view showing a relationship between a supply time of the silicon raw material gas in the late supply stage II, a refractive index of the silicon nitride film and a cycle rate when the silicon nitride film is formed.

As shown in FIG. 7, in the late supply stage II, the refractive index of the silicon nitride film 1 tends to increase as the supply time of the silicon raw material gas increases (see a refractive index: “Δ” in the left vertical axis). For example, when processing conditions other than the processing time are set equal to those described in the “late supply stage II” as described above in <2. Supply Process of Silicon Raw Material Gas>, the refractive index, for example, changes as follows:

About 2.14 at Processing Time of 30 sec

About 2.18 at Processing Time of 40 sec

About 2.245 at Processing Time of 55 sec

As described above, the refractive index (composition ratio) of the silicon nitride film 1 may be controlled by adjusting the supply time of the silicon raw material gas in the late supply stage II (see the referential mark V in FIG. 5).

Also, in the late supply stage II, a cycle rate per unit time shown in FIG. 7 is also improved as the supply time of the silicon raw material gas increases (see a cycle rate: “◯” in the right vertical axis). Because the supply amount of the silicon raw material gas per cycle, as shown in FIG. 3, is increased when the supply time is increased, the silicon film formed on the wafer W is thickened as much as the supply amount increases.

<Relationship Between Processing Pressure of Late Supply Stage II and in-Plane Uniformity of Silicon Nitride Film>

In the first embodiment, a batch type film forming apparatus, in which the plurality of, e.g., 50 to 120, wafers W are mounted on the wafer boat 105 in multi stages and thin films are formed on the respective wafers W in a lump, is used to form the silicon nitride film 1.

The above-described <2. Supply Process of Silicon Raw Material Gas> was performed in a state where the opening degree of the APC 133 is maintained at 25%. The opening degree of the APC 133 has a relationship with the internal pressure of the processing chamber 101 in <2. Supply Process of Silicon Raw Material Gas>. If the opening degree of the APC 133 is reduced below the above-described 25%, for example, to 15%, 5% or the like, the internal pressure of the processing chamber 101 in the supply process of the silicon raw material gas is increased. On the contrary, if the opening degree of the APC 133 is set to 35% or the like, the internal pressure of the processing chamber 101 in the supply process of the silicon raw material gas is decreased.

It has been found by the present inventors that the internal pressure of the processing chamber 101 in the supply process of the silicon raw material gas, particularly, in the late supply stage II (see the referential mark VI in FIG. 5) is related to the wafer in-plane uniformity.

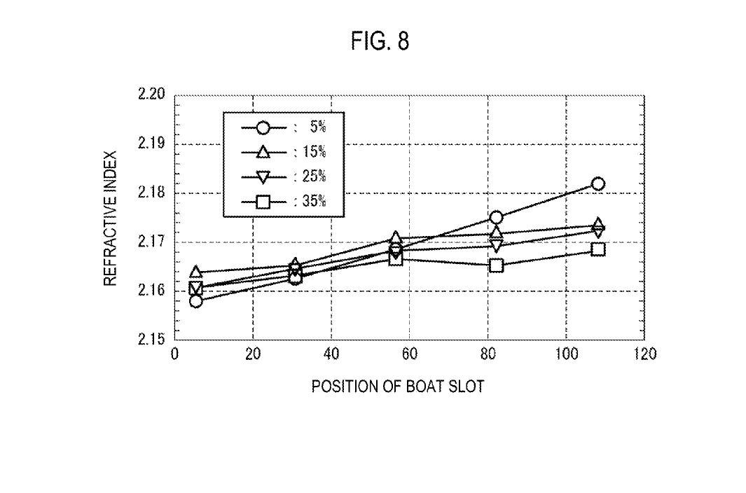

FIG. 8 is a view showing a relationship between a position of a boat slot and a refractive index of a silicon nitride film.

As shown in FIG. 8, if the opening degree of the APC 133 falls within a range of 15% to 35%, the refractive index of the silicon nitride film 1 only has a difference (maximum value−minimum value) of about 0.01, for example, when the number of the boat slot is in a range between 5 and 110. However, if the opening degree is reduced to 5%, the difference is increased to about 0.024. The difference between “the maximum value and the minimum value” of specific refractive indexes is as follows:

Opening Degree of 5%: About 0.024 (“◯” in FIG. 8)

Opening Degree of 15%: About 0.01 (“Δ” in FIG. 8)

Opening Degree of 25%: About 0.012 (“∇” in FIG. 8)

Opening Degree of 35%: About 0.009 (“□” in FIG. 8).

Therefore, in order to obtain good wafer in-plane uniformity according to the refractive indexes of the silicon nitride film 1, for example, suppressing the difference between “the maximum value and the minimum value” of the refractive indexes within ±0.02, the opening degree of the APC 133 needs to be in a range of 15% to 35%. In this example, when the opening degree of the APC 133 is 25%, the internal pressure of the processing chamber 101 is about 133 Pa (1 Torr).

Also, in this example, if the opening degree of the APC 133 is in a range of 15% to 35%, the internal pressure of the processing chamber 101 falls within a range of 96 to 140 Pa (0.72 to 1.05 Torr).

Therefore, the internal pressure of the processing chamber 101 in the supply process of the silicon raw material gas, particularly, in the late supply stage II, is set in a range of not more than 140 Pa (1.05 Torr). Then, it is possible to obtain good wafer in-plane uniformity according to refractive indexes of the silicon nitride film 1.

As described above, according to the first embodiment of the present disclosure, the following advantages are obtained:

(1) By dividing the supply process of the silicon raw material gas into the two stages, i.e., the initial supply stage I and the late supply stage II, it possible to improve the wafer in-plane uniformity of thickness for the silicon nitride film 1 even for the Si-rich silicon nitride film 1 (in the Si₃N₄ composition). In addition, the wafer in-plane uniformity can be controlled by adjusting the peak value of the internal pressure of the processing chamber 101 in the initial supply stage I.

(2) Further, the refractive index (composition ratio) of the silicon nitride film 1 can be controlled by adjusting the supply time of the silicon raw material gas in the late supply stage II (see the referential mark V in FIG. 5).

(3) For the batch type film forming apparatus, the wafer in-plane uniformity can be controlled by adjusting the internal pressure of the processing chamber 101 in the supply process of the silicon raw material gas, particularly, in the late supply stage II.

### Second Embodiment

A second embodiment relates to another gas supply adjusting unit.

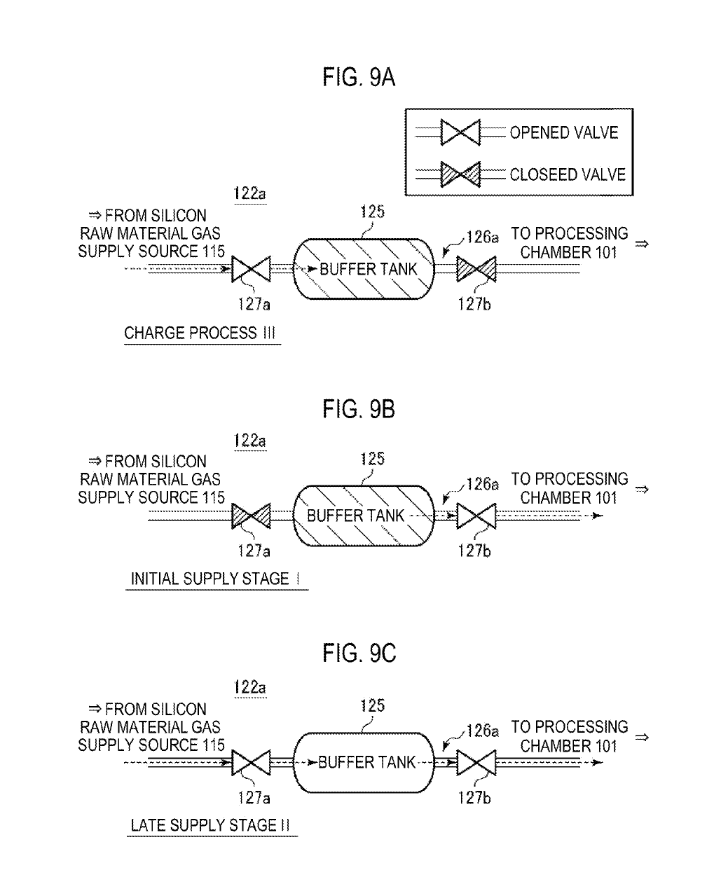

FIGS. 9A to 9C are views showing main operation states of another gas supply adjusting unit according to the second embodiment, which is provided in the film forming apparatus instead of the gas supply adjusting unit 122 shown in FIG. 1.

As shown in FIGS. 9A to 9C, a gas supply adjusting unit 122a according to the second embodiment is different from the gas supply adjusting unit 122 provided in the film forming apparatus 100 described with reference to FIG. 1 in that the gas supply adjusting unit 122a includes only the gas supply channel 126a with the buffer tank 125.

In the gas supply adjusting unit 122a, the charge process III, the initial supply stage I and the late supply stage II that are described with reference to FIG. 3 are performed as follows.

### <Charge Process III>

As shown in FIG. 9A, the charge of the buffer tank 125 with the silicon raw material gas is achieved by closing the opening/closing valve 127b disposed at the gas outlet side in the gas supply channel 126a. In such a state, the silicon raw material gas is supplied from the silicon raw material gas supply source 115 into the buffer tank 125 through the mass flow controller 121a. Accordingly, in the same way as the first embodiment, an internal pressure of the charged buffer tank 125 is set to be in a range of, for example, 13,300 to 53,200 Pa (100 to 400 Torr).

### <Initial Supply Stage I>

As shown in FIG. 9B, the discharge of the silicon raw material gas from the buffer tank 125 is achieved by closing the opening/closing valve 127a disposed at the gas inlet side in the gas supply channel 126a, and opening the opening/closing valve 127b disposed at the gas outlet side in the gas supply channel 126a. Thus, in a manner similar to the first embodiment, the silicon raw material gas is discharged from the buffer tank 125.

### <Late Supply Stage II>

As shown in FIG. 9C, the opening/closing valve 127a disposed at the gas inlet side in the gas supply channel 126a and the opening/closing valve 127b disposed at the gas outlet side thereof are respectively opened so that the buffer tank 125 is used as a gas supply channel through which the silicon raw material gas passes. This configuration, similar to the first embodiment, makes it possible to supply the silicon raw material gas into the processing chamber 101 while adjusting a flow rate of the silicon raw material gas supplied from the silicon raw material gas supply source 115 by the MFC 121a.

According to the gas supply adjusting unit 122a configured as above, even when there is provided only the gas supply channel 126a including the buffer tank 125, the same method as the silicon nitride film forming method described in the first embodiment may be implemented.

### Third Embodiment

A third embodiment is related to another film forming apparatus which is capable of performing the silicon nitride film forming method according to the first embodiment even when neither the gas supply adjusting unit 122 nor the gas supply adjusting unit 122a is provided.

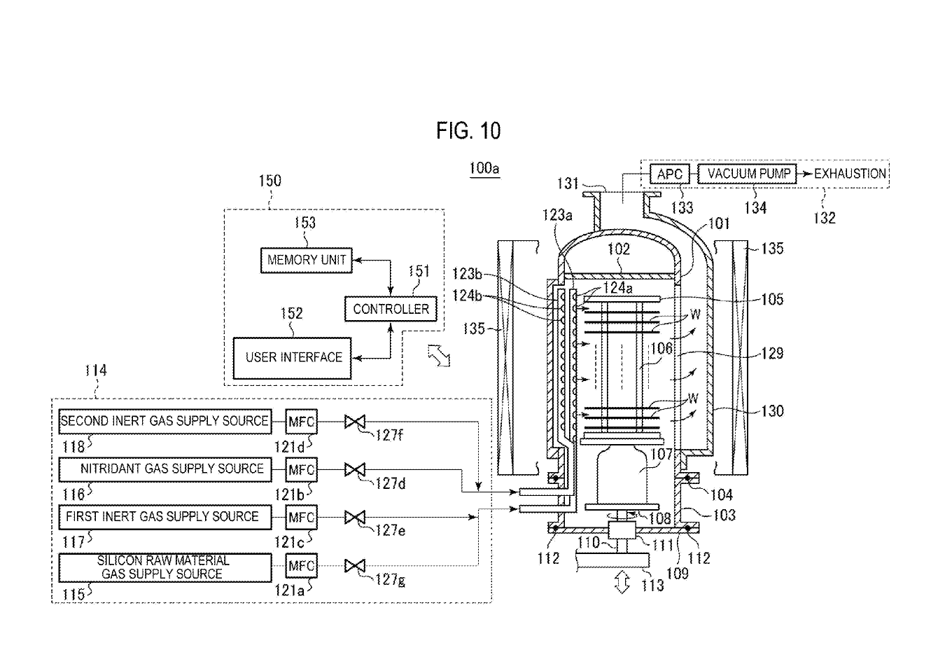

FIG. 10 is a sectional view schematically showing another film forming apparatus, which is capable of performing the silicon nitride film forming method according to the embodiment of the present disclosure.

As shown in FIG. 10, a film forming apparatus 100a according to the third embodiment is different from the film forming apparatus 100 described with reference to FIG. 1 in that the film forming apparatus 100a is provided without the gas supply adjusting unit 122 but instead an opening/closing valve 127g.

In the film forming apparatus 100a, the silicon nitride film forming method according to the embodiment of the present disclosure may be implemented by controlling the opening degree of the automatic pressure controller (APC) 133.

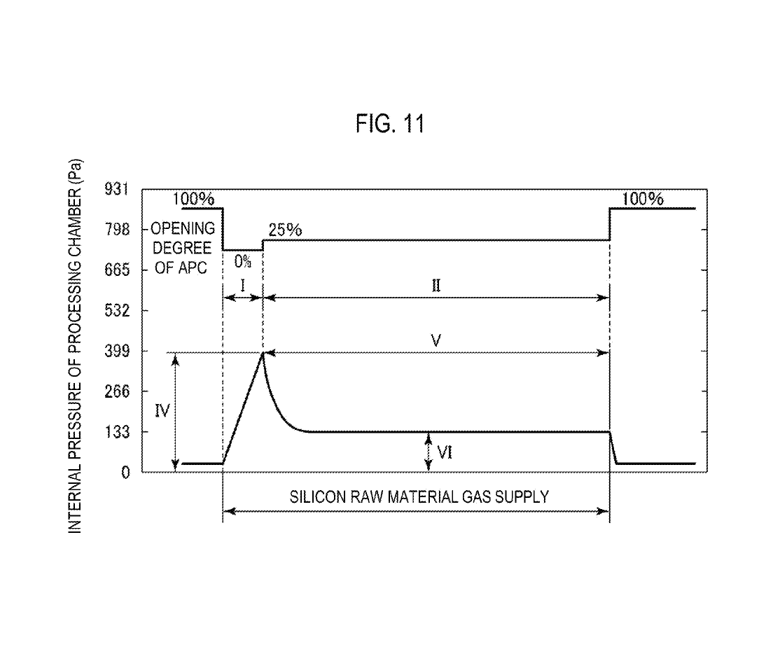

FIG. 11 is a view showing a relationship between an opening degree of the APC 133 and an internal pressure of the processing chamber 101 in the supply process of the silicon raw material gas according to the third embodiment of the present disclosure.

As shown in FIG. 11, before entering the initial supply stage I, a purge process is performed. For this reason, the opening degree of the APC 133 is set to 100% (=OPEN).

When entering the initial supply stage I after the purge process, the opening degree of the APC 133 is reduced. In this example, the opening degree of the APC is set to be 0% (=CLOSE). In such a state, the opening/closing valve 127g of the film forming apparatus 100a shown in FIG. 10 is opened so that the silicon raw material gas is supplied into the processing chamber 101 while adjusting a flow rate of the silicon raw material gas supplied from the silicon raw material gas supply source 115 by the MFC 121a. Since the opening degree of the APC is 0%, the internal pressure of the processing chamber 101 increases. In this example, the internal pressure of the processing chamber 101 in the initial supply stage I is not increased as much as in the first embodiment using the discharge of the silicon raw material gas from the buffer tank 125 but may be increased up to, for example, 399 Pa.

Thereafter, the opening degree of the APC 133 is increased to 25%. Accordingly, the internal pressure of the processing chamber 101 starts to decrease, and the late supply stage II is entered. Finally, the internal pressure of the processing chamber 101 is converged into a value determined by the flow rate adjusted by the MFC 121a and the opening degree of the APC 133.

After a lapse of a period of a processing time of the late supply stage II, the supply of the silicon raw material gas is stopped. Subsequently, the second inert gas is supplied from the second inert gas supply source 118 into the processing chamber 101 such that the interior of the processing chamber 101 is purged with the second inert gas.

As described above, according to the third embodiment, the same silicon nitride film forming method as the method according to the first embodiment can be implemented using the film forming apparatus 100a not provided with the gas supply adjusting unit 122 by controlling the opening degree of the APC 133.

In some embodiments, the flow rate of the silicon raw material gas may be changed in the course of supply of the silicon raw material gas, for example, to be large in the initial supply stage I and small in the late supply stage II. This configuration makes it possible to control the peak value IV of the internal pressure of the processing chamber 101 in the initial supply stage I.

Further, the opening degree of the APC 133 in the initial supply stage I is not limited to 0% but may be less than the opening degree in the late supply stage II.

In addition, the film forming apparatus 100a can control the processing time V and the internal pressure VI of the processing chamber 101 in the late supply stage II in a manner analogous to the first embodiment.

Although the present disclosure has been described according to the some embodiments, the present disclosure is not limited thereto. A variety of modifications may be made without departing from the spirit of the disclosures.

In the above embodiment, the specific processing conditions have been described, but are not limited thereto. As an example, the processing conditions may be arbitrarily changed depending on a volume of the processing chamber 101 or the like.

Further, in the above embodiment, the chlorosilane-based gas such as the DCS gas has been described to be used as the silicon raw material gas, but is not limited thereto. As an example, gas including at least one of the followings may be used as the chlorosilane-based gas:

monochlorosilane (SiH₃Cl),

dichlorosilane (SiH₂Cl₂),

dichlorodisilane (Si₂H₄Cl₂),

tetrachlorodisilane (Si₂H₂Cl₄),

hexachlorodisilane (Si₂Cl₆), and

octachlorotrisilane (Si₃Cl₈).

In some embodiments, the chlorosilane-based gas may be a hydride of silicon represented by SiₙH₂ₙ (wherein n is a natural number equal to or greater than one) with at least one of hydrogen atoms substituted by a chlorine atom.

Further, a silane-based gas may be used as the silicon raw material gas. Examples of the silane-based gas may include a hydride of silicon represented by SiₘH₂ₘ₊₂ and a hydride of silicon represented by SiₙH₂ₙ. A typical example thereof may include gas including at least one of the followings:

monosilane (SiH₄),

disilane (Si₂H₆),

trisilane (Si₃H₈),

tetrasilane (Si₄H₁₀),

pentasilane (Si₅H₁₂),

hexasilane (Si₆H₁₄),

heptasilane (Si₇H₁₆),

cyclotrisilane (Si₃H₆),

cyclotetrasilane (Si₄H₈),

cyclopentasilane (Si₅H₁₀),

cyclohexasilane (Si₆H₁₂), and

cycloheptasilane (Si₂H₁₄).

In addition, an aminosilane-based gas may also be used as the silicon raw material gas.

A typical example of the aminosilane-based gas may include gas including at least one of the followings:

BAS (butylaminosilane),

BTBAS (bis(tertiary-butylamino)silane),

DMAS (dimethylaminosilane),

BDMAS (bis(dimethylamino)silane),

TDMAS (tri(dimethylamino)silane),

DEAS (diethylaminosilane),

BDEAS (bis(diethylamino)silane),

DPAS (dipropylaminosilane), and

DIPAS (diisopropylaminosilane).

In the above, the ammonia gas has been described to be used as the nitridant gas, but is not limited thereto.

Also, while in the above embodiment, the thermal ALD method has been exemplified as the film forming method, a thermal CVD method, a plasma ALD method using plasma or a plasma CVD method may also be used. Further, the present disclosure allows the silicon raw material gas to be spread wide to the central portion of the object to be processed such as the semiconductor wafer W by making the internal pressure of the processing chamber 101 in the initial supply stage of the silicon raw material gas higher than the internal pressure of the processing chamber 101 in the late supply stage.

Therefore, the present disclosure is effective particularly in processing an object on which the silicon raw material gas is difficult to be spread wide to the central portion of the object to be processed. Such an object would be, for example, a large diameter object to be processed such as a semiconductor wafer W having a diameter of 200 to 450 mm.

According to the present disclosure, it is possible to form a silicon nitride film without degrading a wafer in-plane uniformity of film thickness even when the silicon nitride film is a Si-rich silicon nitride film (in Si₃N₄ composition).

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a silicon nitride film on an object to be processed, the method comprising:
supplying a silicon raw material gas into a processing chamber; and
supplying a nitridant gas into the processing chamber,
wherein supplying the silicon raw material gas includes an initial supply stage in which the silicon raw material gas is initially supplied and a late supply stage following the initial supply stage,
wherein a first internal pressure of the processing chamber defined in the initial supply stage is lower than a second internal pressure of the processing chamber defined in the late supply stage.

2. The method of claim 1, wherein the silicon nitride film formed on the object to be processed has a refractive index of more than 2.0.

3. The method of claim 1, wherein the silicon nitride film is formed on the object to be processed by repeatedly supplying the silicon raw material gas and the nitridant gas.

4. The method of claim 1, wherein an in-plane uniformity of thickness of the silicon nitride film formed on the object to be processed is controlled by controlling the first internal pressure in the initial supply stage.

5. The method of claim 1, wherein a refractive index of the silicon nitride film formed on the object to be processed is controlled by controlling a time interval in the late supply stage.

6. The method of claim 1, wherein the processing chamber is configured to accommodate a plurality of object to be processed therein, and
wherein an in-plane uniformity of refractive indexes of the silicon nitride films formed on each of the plurality of object to be processed is controlled by controlling the second internal pressure in the late supply stage.

7. The method of claim 1, wherein in the initial supply stage, the silicon raw material gas is supplied into the processing chamber by discharging the silicon raw material gas from a tank in which the silicon raw material gas is temporarily charged, and
wherein in the late supply stage, the silicon raw material gas is supplied from a silicon raw material gas supply mechanism configured to supply the silicon raw material gas into the processing chamber while adjusting a flow rate thereof.

8. The method of claim 7, wherein the first internal pressure is controlled by controlling a time period of a charge of the silicon raw material gas into the tank.

9. The method of claim 8, wherein a pressure of the charge of the silicon raw material gas into the tank is controlled by adjusting the time period of charge.

10. The method of claim 8 wherein the charge of the silicon raw material gas into the tank is performed in the course of supplying the nitridant gas.

11. The method of claim 1, wherein the processing chamber includes a valve which controls an opening degree and a pressure adjusting mechanism configured to adjust the internal pressure of the processing chamber is connected to the processing chamber,
wherein a first opening degree of the valve defined in the initial supply stage is larger than a second opening degree of the valve defined in the late supply stage.

12. The method of claim 11, wherein the valve is maintained in a closed state during the initial supply stage.

13. A film forming apparatus, comprising:
a processing chamber in which a film forming processing is performed on an object to be processed;
a silicon raw material gas supply mechanism configured to supply a silicon raw material gas into the processing chamber;
a nitridant gas supply mechanism configured to supply a nitridant gas into the processing chamber;
a pressure adjusting mechanism configured to adjust an internal pressure of the processing chamber;
a tank configured to be temporarily charged with the silicon raw material gas supplied from the silicon raw material gas supply mechanism; and
a control unit configured to control the film forming processing such that the method of claim 1 is performed.

14. A film forming apparatus, comprising:
a processing chamber in which a film forming processing is performed on an object to be processed;
a silicon raw material gas supply mechanism configured to supply a silicon raw material gas into the processing chamber;
a nitridant gas supply mechanism configured to supply a nitridant gas into the processing chamber;
a pressure adjusting mechanism configured to adjust an internal pressure of the processing chamber; and
a control unit configured to control the film forming processing such that the method of claim 1 is performed.
